(19) United States
(12) Patent Application Publication
(10) Pub. No.: US 2024/0243070 A1
(43) Pub. Date: Jul. 18, 2024

(54) ELECTRONIC DEVICE

(71) Applicant: Japan Display Inc., Tokyo (JP)

(72) Inventor: Takumi SANO, Tokyo (JP)

(21) Appl. No.: 18/402,821

(22) Filed: Jan. 3, 2024

(30) Foreign Application Priority Data
Jan. 13, 2023 (JP) 2023-003662

(51) Int. Cl. H01L 23/538

(52) U.S. Cl. CPC H01L 23/5386; H01L 23/5387; H01L 25/18

(57) ABSTRACT

To realize a stretchable electronic device having high reliability.

The configuration of the present invention is as follows. In a stretchable electronic device in which an active area and a terminal area are continuously formed, a scanning line having a meander structure and a signal line having a meander structure are formed in the active area, a terminal connected to a wiring substrate is formed in the terminal area on the opposite side of the active area, an electronic component is mounted in the terminal area, a first terminal wiring having a meander structure is formed between the active area and the electronic component, and a second terminal wiring having a meander structure is formed between the electronic component and the terminal.

### CLAIM OF PRIORITY

The present application claims priority from Japanese Patent Application JP 2023-3662 filed on Jan. 13, 2023, the content of which is hereby incorporated by reference into this application.

### BACKGROUND OF THE INVENTION

### 1. Field of the Invention

The present invention relates to a flexible and stretchable electronic device.

### 2. Description of the Related Art

The demand for flexible or stretchable electronic devices has been increasing. Applications of such a stretchable electronic device include, for example, pasting it to the housing of an electronic apparatus having a curved surface, attaching it to a display medium having a curved surface, and attaching it to a human body or the like as a sensor. Elements include, for example, sensors such as a touch sensor, a temperature sensor, a pressure sensor, and an acceleration sensor, or light emitting elements, and light valves that configure various display devices.

In a sensor device, scanning lines and signal lines are used to control each element. It is necessary for a stretchable electronic device to be resistant to bending and stretching. Japanese Patent Laid-open No. 2021-106199 describes a configuration resistant to bending and stretching by meandering scanning lines and video signal lines (hereinafter, also referred to as a meander structure).

### SUMMARY OF THE INVENTION

By allowing scanning lines and signal lines to have a meander structure, a certain degree of resistance to stretching or bending the stretchable electronic device can be obtained. Even for a stretchable display device, power and signals need to be supplied from the outside. Such supply of power and signals is performed through a flexible wiring substrate.

Incidentally, the flexible wiring substrate can be flexibly bent, but cannot be expected to be stretched. Thus, if the stretchable electronic device is stretched, stress is generated between the flexible wiring substrate and the display device. In addition, the flexible wiring substrate is often used while being bent, and when being bent, stress is likely to be generated between the flexible wiring substrate and the stretchable electronic device.

The connection between the flexible wiring substrate and the stretchable display device is made through a plurality of terminals. Therefore, this stress is generated at the terminals. When the stress increases, the terminals are peeled off. In addition, even in the case where the peel-off does not occur, connection resistance at the terminals becomes large. The change in connection resistance is observed as noise.

An object of the present invention is to avoid stress at a connection part between a flexible wiring substrate and a stretchable electronic device, and to prevent connection failure or noise from being generated at the connection part. in addition, the present invention realizes a highly-reliable and stretchable electronic device.

The present invention realizes the above object, and representative means is as follows.

(1) In a stretchable electronic device in which an active area and a terminal area are continuously formed, a scanning line having a meander structure and a signal line having a meander structure are formed in the active area, a terminal connected to a wiring substrate is formed in the terminal area on an opposite side of the active area, an electronic component is mounted in the terminal area, a first terminal wiring having a meander structure is formed between the active area and the electronic component, and a second terminal wiring having a meander structure is formed between the electronic component and the terminal.

(2) In a stretchable electronic device in which an active area and a terminal area are continuously formed, a scanning line having a meander structure and a signal line having a meander structure are formed in the active area, a terminal connected to a wiring substrate is formed in the terminal area on an opposite side of the active area, a terminal wiring having a meander structure is formed in the terminal area, and Young's modulus of the terminal area in a plane direction is larger than that of the active area in the plane direction.

(3) In a stretchable electronic device in which an active area and a terminal area are continuously formed, a scanning line having a meander structure and a signal line having a meander structure are formed in the active area, a terminal connected to a wiring substrate is formed in the terminal area on an opposite side of the active area, a linear terminal wiring is formed in the terminal area, and Young's modulus of the terminal area in a plane direction is larger than that of the active area in the plane direction.

### BRIEF DESCRIPTION OF THE DRAWINGS

FIG. 1 is a plan view of a stretchable electronic device as a comparative example;

FIG. 2 is an A-A cross-sectional view of FIG. 1;

FIG. 3 is an enlarged plan view of an active area;

FIG. 4 is a B-B cross-sectional view of FIG. 3;

FIG. 5 is a C-C cross-sectional view of FIG. 3;

FIG. 6 is a plan view for depicting an element and surroundings thereof;

FIG. 7 is a D-D cross-sectional view of FIG. 6;

FIG. 8 is a plan view of a stretchable electronic device of a first embodiment;

FIG. 9 is an E-E cross-sectional view of FIG. 8;

FIG. 10 is a plan view of terminal parts of the stretchable electronic device of the first embodiment;

FIG. 11 is an F-F cross-sectional view of FIG. 10;

FIG. 12 is a G-G cross-sectional view of FIG. 10;

FIG. 13 is a plan view of the stretchable electronic device depicting another mode of the first embodiment;

FIG. 14 is a plan view of a terminal area of a stretchable electronic device of a second embodiment;

FIG. 15 is an H-H cross-sectional view of FIG. 14;

FIG. 16 is an I-I cross-sectional view of FIG. 14;

FIG. 17 is a plan view of the stretchable electronic device according to another mode of the second embodiment; and

FIG. 18 is a J-J cross-sectional view of FIG. 17.

### DETAILED DESCRIPTION OF THE PREFERRED EMBODIMENTS

The content of the present invention will be described below in detail using embodiments. Hereinafter, an electronic device that is stretchable will also be referred to as a stretchable electronic device.

### First Embodiment

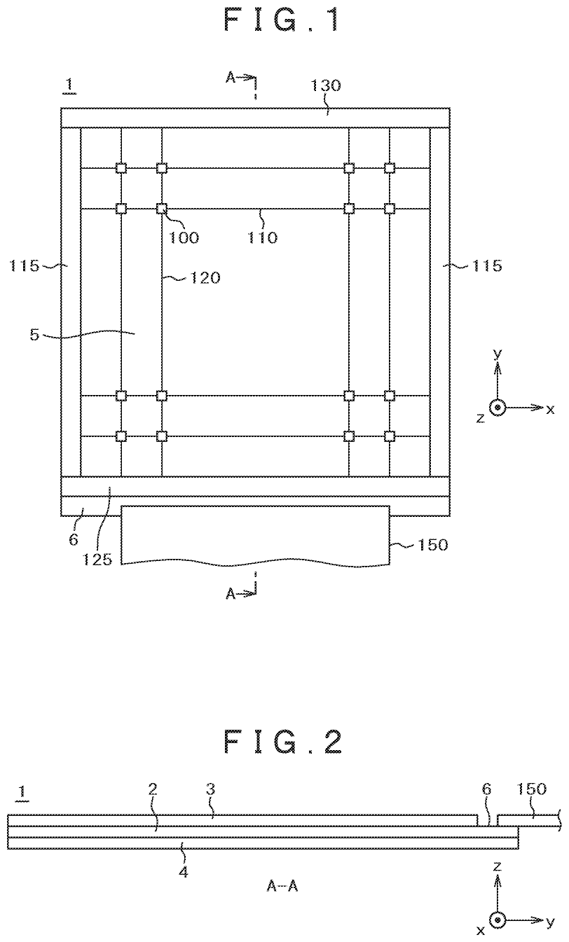

The present invention particularly relates to a configuration of a terminal area of a stretchable electronic device, but since a terminal area 6 is formed at the same time as an active area 5, a configuration of the active area 5 will be described first. FIG. 1 is a plan view of a stretchable electronic device 1 as a first comparative example to describe the configuration of the active area 5. The active areas 5 in the comparative example and the embodiments described later have almost the similar configuration. The stretchable electronic device 1 in FIG. 1 is formed in a flat plate shape as a whole, but can be curved in the z direction or extended on the x-y plane. The break elongation rate, that is, the elongation rate until the stretchable electronic device 1 breaks is different depending on the materials that configure the stretchable electronic device 1, but in the case where extensible organic materials are mainly used, an elongation rate of approximately 30% is possible, or an elongation rate of approximately 60% is also possible in some cases. On the other hand, if relatively large amounts of inorganic materials are used, the elongation rate is approximately 10% to 15%.

In FIG. 1, the stretchable electronic device 1 has a large area occupied by the active area 5. In the active area 5, electronic elements 100 are arranged in a matrix. As the electronic elements 100, a sensor, a semiconductor element, an actuator, and the like can be arranged. As the sensor, for example, a light sensor for detecting visible or infrared light, a temperature sensor, a pressure sensor, or a touch sensor can be arranged. As the semiconductor element, for example, a light emitting element, a light receiving element, a diode, or a transistor can be arranged. As the actuator, for example, a piezo element can be used.

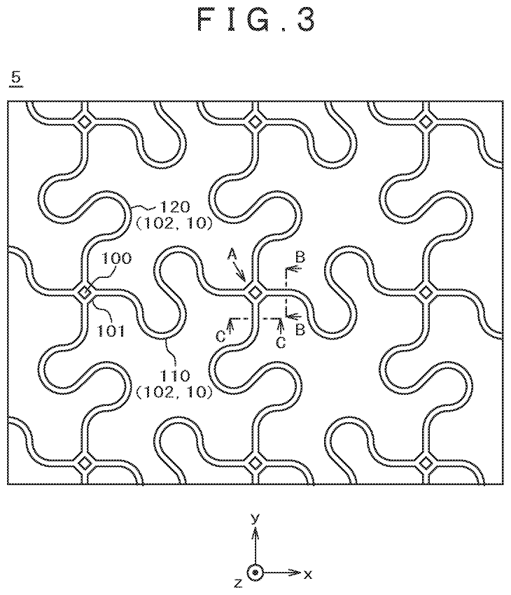

Each electronic element 100 is connected to a scanning line 110 and a signal line 120. The scanning lines 110 extend in the lateral direction (x direction) and are aligned in the vertical direction (y direction), and the signal lines 120 extend in the vertical direction and are aligned in the lateral direction. In FIG. 1, both the scanning lines 110 and the signal lines 120 linearly extend in order not to complicate the drawing, but in reality, the scanning lines 110 extend in the lateral direction in a meandering manner, and the signal lines 120 extend in the vertical direction as depicted in FIG. 3.

In FIG. 1, driving circuits 115 and 125 and the terminal area 6 are arranged outside the active area 5. Scanning line driving circuits 115 are arranged on both sides of the active area 5 in the x direction, a power supply circuit 130 for supplying power to the electronic elements 100 is present on the upper side of the active area 5 in the y direction, and a signal line driving circuit 125 is arranged on the lower side of the active area 5 in the y direction. The terminal area 6 is arranged further below the signal line driving circuit 125. A flexible wiring substrate 150 for supplying power and signals to the stretchable electronic device 1 and for sending signals to the outside is connected to the terminal area 6. It should be noted that although not depicted, the flexible wiring substrate 150 is further connected to another wiring substrate 300 (described later).

FIG. 2 is an A-A cross-sectional view of FIG. 1. FIG. 2 is a schematic cross-sectional view. In FIG. 2, the electronic elements 100, the scanning lines 110, the signal lines 120, and the like described in FIG. 1 are present in an element layer 2. That is, the function as the stretchable electronic device 1 is present in the element layer 2. This element layer 2 is covered with an upper protective layer 3 from the upper side and a lower protective layer 4 from the lower side. Both the upper protective layer 3 and the lower protective layer 4 are formed of a material that can be elastically deformed, that is, small in Young's modulus.

In FIG. 2, the active area 5, the driving circuits 115 and 125, and the like are covered with the upper protective layer 3 and the lower protective layer 4. At an end of the element layer 2, there is a portion that is not covered with the upper protective layer 3, and this portion is the terminal area 6 in the comparative example. The terminal area 6 is protected only by the lower protective layer 4. The flexible wiring substrate 150 is connected to the terminal area 6.

FIG. 3 is an enlarged plan view of the active area 5. FIG. 3 depicts the main constitutional parts of the element layer 2 depicted in FIG. 2. That is, the element layer 2 depicted in FIG. 2 is not present as a single planar substrate, but is, as depicted in FIG. 3, configured using a meander structural part 102 where the scanning line 110 and the signal line 120 are formed, and a base material 10 where an element area 101 formed at the intersection of the scanning line 110 and the signal line 120 is present. In other words, the base material 10 has a net-like structure.

In FIG. 3, the meander structural part 102 and the element area 101 present at the intersection are made of resin such as polyimide. Using this resin as the base material 10, the scanning lines 110, the signal lines 120, the elements 100, and the like are formed thereon. In FIG. 3, the element 100 is present in the element area 101. This configuration is intended to reduce the stress on each component even when the stretchable electronic device 1 is stretched.

In FIG. 3, the diameter of the element 100 in the x direction and the diameter in the y direction are, for example, 100 μm. The pitch of the element 100 in the x direction and the pitch in the y direction are, for example, 250 μm. In addition, the width of the base material 10 including the scanning line 110, the video signal line 120, and the like in the meander structural part 102 is, for example, 30 μm.

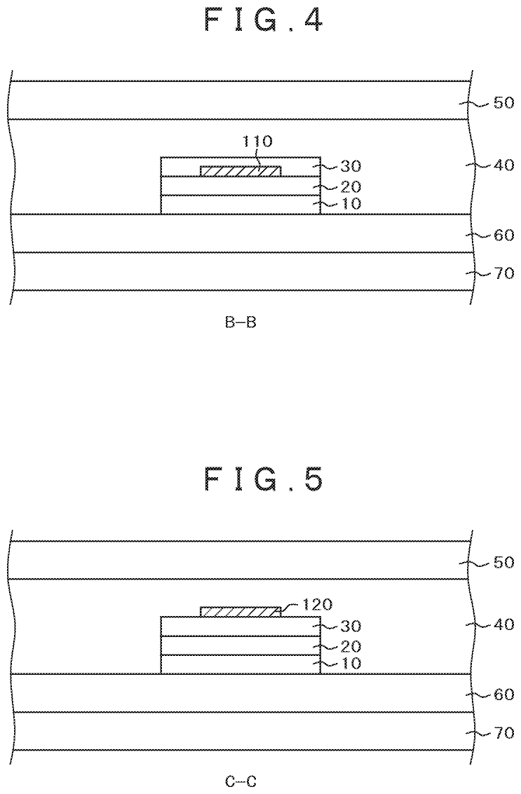

FIG. 4 is a B-B cross-sectional view of FIG. 3 and a cross-sectional view of the meander structural part 102 including the scanning line 110. In FIG. 4, a first organic insulating film 20 is formed on the base material 10. The scanning line 110 is formed on the first organic insulating film 20. A second organic insulating film 30 is formed by covering the scanning line 110. The plan view of the meander structural part 102 including the scanning line 110 in FIG. 3 depicts the planar shape of the base material 10.

The base material 10, the first organic insulating film 20, and the second organic insulating film 30 are formed of, for example, polyimide. Polyimide is preferable as the base material 10 of the scanning line 110 and the signal line 120 because of excellent performance in mechanical strength, heat resistance, and the like. That is, in the case where the stretchable electronic device 1 is stretched, the stress generated in the meander structural part 102 is received by polyimide forming the base material 10, the first organic insulating film 20, and the like, and thus the stress on the scanning line 110 and the like formed of metal is reduced.

The scanning line 110 has, for example, a titanium-aluminum-titanium (Ti—Al—Ti, TAT) structure. In the three-layer structure, the conductivity is mainly assumed by Al, and Ti is used to protect Al or improve bonding with other wirings. In addition to this, the material of the scanning line 110 can be variously configured depending on the application of the stretchable electronic device 1, such as molybdenum-tungsten alloy (MoW).

As depicted in FIG. 3, the meander structural part 102 (hereinafter, also simply referred to as the scanning line 110) having the scanning line 110 is fixed by the protective layers (3 and 4 depicted in FIG. 2) from the top and bottom because the shape is unstable. First, the meander structural part 102 with the scanning line 110 formed is covered with an upper buffer layer 40 formed of an organic material. The upper side thereof is covered with a protective layer 50 formed of an organic material. A lower buffer layer 60 formed of an organic material is arranged on the lower surface of the base material 10, and a lower protective layer 70 made of an organic material is formed thereunder.

As described above, the buffer layers 40 and 60 and the protective layers 50 and 70 arranged above and below stabilize the shape. Incidentally, since the electronic device of the present invention is a stretchable electronic device, it is necessary to be stretchable against external tensile stress. Therefore, the buffer layers 40 and 60 and the protective layers 50 and 70 sandwiching the meander structural part 102 are desirably made of materials that are easier to extend than polyimide forming the base material 10, the first organic insulating film 20, and the like, that is, materials that are small in Young's modulus. Such materials include resin such as acrylic, urethane, epoxy, and silicone.

FIG. 5 is a C-C cross-sectional view of FIG. 3 and a cross-sectional view of the meander structural part 102 having the signal line 120. In the meander structural part 102 of FIG. 5, the first organic insulating film 20 and the second organic insulating film 30 are continuously formed on the base material 10. The signal line 120 is formed on the second organic insulating film 30. In the first embodiment, the signal line 120 has the same material as the scanning line, that is, the Ti—Al—Ti (TAT) structure, but may be changed to other materials depending on the application of the stretchable electronic device. The other structures are the same as the cross-sectional shape of the scanning line 110 part described in FIG. 4.

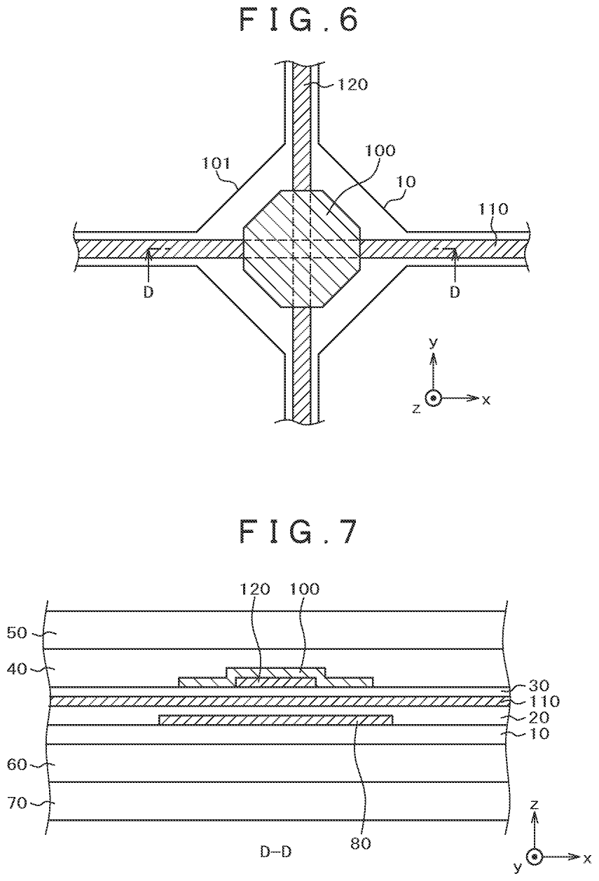

FIG. 6 is an enlarged plan view of the element area 101. The element area 101 consists of the base material 10 formed in an island shape. The element area 101 in FIG. 6 is roughly shaped like an octagon, but other shapes may be used. In FIG. 6, both the scanning line 110 and the signal line 120 are straight lines, but have the meander structure as depicted in FIG. 3 on the outer side of FIG. 6.

In FIG. 6, the element 100 is arranged in the element area 101. In the element area 101, the signal line 120 and the scanning line 110 intersect with each other through an insulating film. However, FIG. 6 is a schematic diagram, and in an actual device, both the scanning line 110 and the video signal line 120 are connected to a transistor or the like that drives the element 100.

FIG. 7 is a D-D cross-sectional view of FIG. 6. In FIG. 7, an inorganic insulating film 80 is formed on the base material 10. The inorganic insulating film 80 blocks impurities and the like entering from the lower side to the element 100 and the like formed on the upper side thereof. In FIG. 7, the inorganic insulating film 80 is formed on the base material 10, but this is an example and may be formed in a layer closer to the element 100 as needed.

The inorganic insulating film 80 is formed of a silicon nitride film (SiN film), a silicon oxide film (SiO film), or a laminated film of these. In some cases, an aluminum oxide film (AlO) is used. Since the inorganic insulating film 80 is high in rigidity but is formed only in the element area 101, it has a small effect on the stretchability of the stretchable electronic device 1.

The first organic insulating film 20 made of, for example, polyimide is formed by covering the inorganic insulating film 80. The scanning line 110 extends in the lateral direction (x direction) on the first organic insulating film 20. The second organic insulating film 30 made of, for example, polyimide is formed by covering the scanning line 110 and the first organic insulating film 20. The signal line 120 extends in the y direction on the second organic insulating film 30.

Then, the element 100 is arranged by covering the signal line 120. FIG. 7 is a schematic diagram, and the connection structures among the element 100 and the scanning line 110, the signal line 120, and the like are omitted. As an example, a thin-film transistor (TFT) is arranged between the element 100 and the scanning line 110 or the signal line 120, and signals from the element 100 or signals to the element 100 are controlled by controlling the thin-film transistor with a scanning line control circuit 115 and a signal line control circuit 125.

The wiring structure between the element 100 and the signal line 120 in FIG. 7 differs depending on what is arranged as the element 100 in FIG. 7. There is a possibility that a plurality of organic or inorganic insulating films is formed in the element area 101.

The planar structure depicted in FIG. 6 corresponds to the cross-sectional structure from the base material 10 to the element 100 in FIG. 7. If the structure is as it is, the plane shape becomes as depicted in FIG. 3 and is unstable. Therefore, as described in FIG. 4, the upper buffer layer 40, the upper protective layer 50, the lower buffer layer 60, and the lower protective layer 70 are formed, and the entire structure is consolidated into a flat plate to stabilize the shape. In addition, as described in FIG. 4, since the materials that are smaller in Young's modulus than the base material 10, the first organic insulating film 20, the second organic insulating film 30, and the like are used for the upper buffer layer 40, the upper protective layer 50, the lower buffer layer 60, and the lower protective layer 70, the stretchable electronic device 1 is configured not to impair the stretchability.

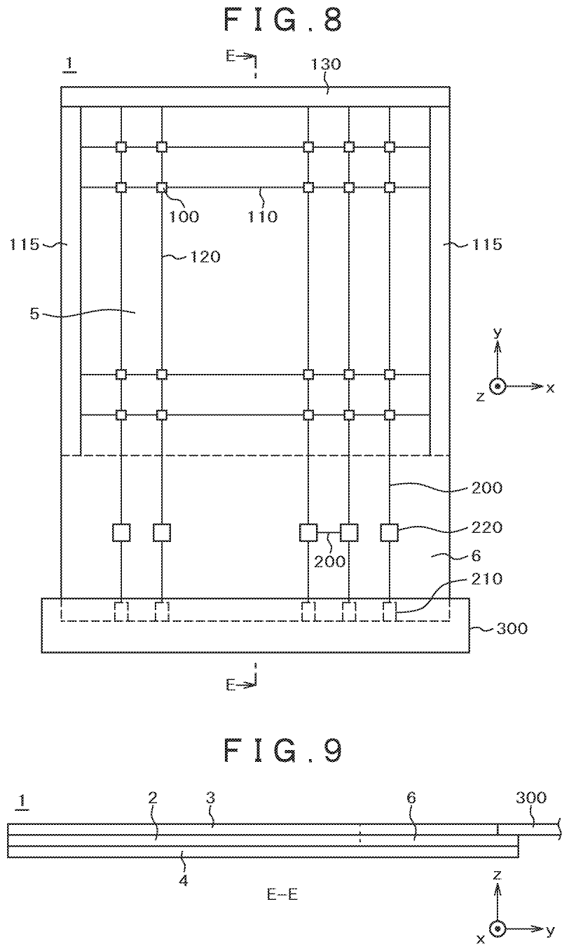

FIG. 8 is a plan view of a stretchable electronic device 1 according to the first embodiment. In FIG. 8, the configuration of an active area 5 is the same as described in the comparative example. In FIG. 8, unlike the first embodiment, there is no flexible wiring substrate 150. In the configuration of FIG. 8, a terminal area 6 is long in the vertical direction (y direction), and a wiring substrate 300 is directly connected to the terminal area 6.

The wiring substrate 300 may have a rigid configuration instead of a flexibly curved configuration. As a rigid wiring substrate, for example, there is a configuration in which electronic components such as ICs are mounted on glass epoxy. The Young's modulus of the rigid wiring substrate 300 is larger than that of the flexible wiring substrate 150.

That is, in FIG. 8, the terminal area 6 that is long in the vertical direction is made to play the role of the flexible wiring substrate 150 depicted in FIG. 1. That is, not only terminal wirings 200 for connecting the active area 5 to the wiring substrate 300, but also driver ICs, capacitors, resistors, and the like that are mounted on the flexible wiring substrate 150 are mounted on the terminal area 6. Hereafter, the driver ICs, the capacitors, the resistors, and the like will be simply represented by the word of electronic components 220.

The terminal wiring 200 is described using a straight line in FIG. 8, but actually has a meander structure as depicted in FIG. 10. In addition, the cross-sectional structure of the terminal area 6 is also the same as that of the active area 5. That is, the terminal area 6 also has a stretchable configuration.

In FIG. 8, signal lines 120 or scanning lines 110 in the active area 5 continuously extend in the terminal area 6 as the terminal wirings 200. In the terminal area 6, the signal lines 120 or the scanning lines 110 are connected to the wiring substrate 300 through the electronic components 220.

Further, the terminal area 6 of the stretchable electronic device 1 has a more flexible configuration than the flexible wiring substrate 150. Therefore, even in the case where the terminal area 6 is curved, the stress generated in the terminal area 6 is small because it easily follows the curved shape. In addition, by directly connecting to the wiring substrate 300 without using the flexible wiring substrate 150, the number of connection areas with other members can be reduced. With such a configuration, the reliability of the connection in the electronic device 1 connected to the wiring substrate 300 can be improved.

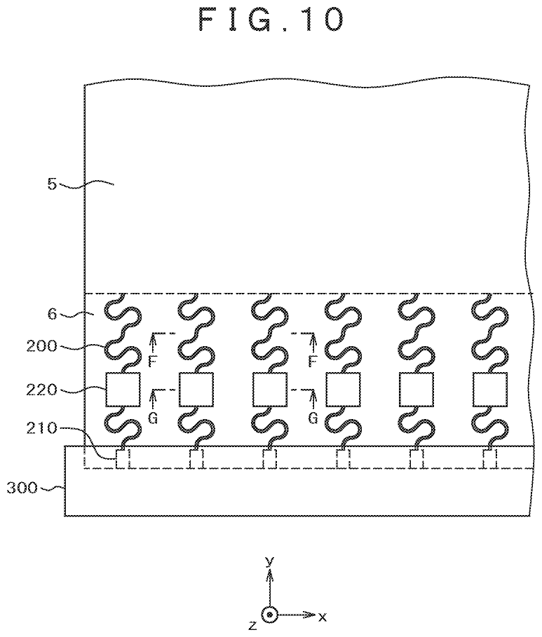

FIG. 9 is an E-E cross-sectional view of FIG. 8. In FIG. 9, the length of the terminal area 6 in the y direction is relatively longer than that in FIG. 2. In FIG. 9, the terminal area 6 is connected to not the flexible wiring substrate 150 but the wiring substrate 300. In FIG. 9, the active area having an element layer 2 and the terminal area 6 are separated by a dotted line, but the terminal area 6 and the active area 5 are integrally formed.

FIG. 10 is a detailed plan view of the terminal area 6. In FIG. 10, the boundary between the active area 5 and the terminal area 6 is indicated by a dotted line. However, the active area 5 and the terminal area 6 are continuously formed. That is, the active area 5 and the terminal area 6 are formed on the same substrate 10. In addition, in the example depicted in FIG. 10, the terminal wirings 200 also have a meander structure as similar to the signal lines 120 and the scanning lines 110 in the active area 5. As depicted in FIG. 10, the electronic components 220 are mounted on the terminal area 6. The electronic components 220 and terminals 210 are also connected to each other through the terminal wirings 200 having a meander structure. Then, the wiring substrate 300 is connected to the terminal area 6 through the plurality of terminals 210.

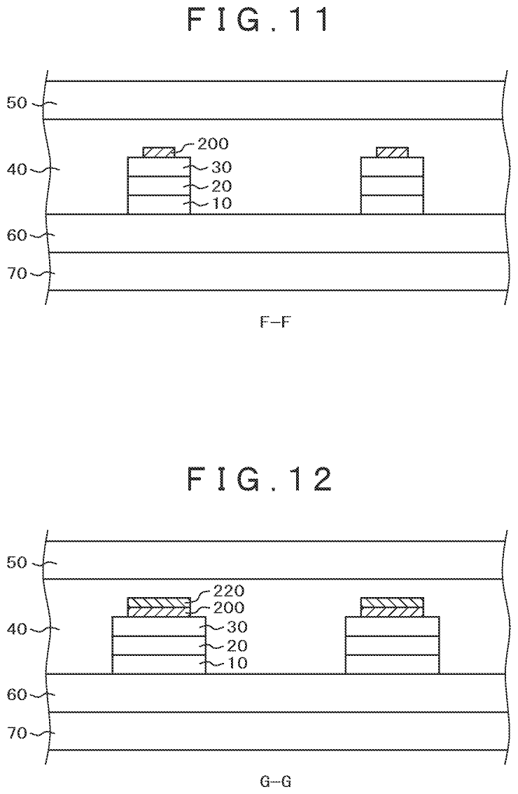

FIG. 11 is an F-F cross-sectional view of FIG. 10. FIG. 11 is the same as FIG. 5 depicting a cross-sectional view of the active area 5 except that two lines are illustrated. It should be noted that in FIG. 11, the wiring arranged on a second organic insulating film 30 is the terminal wiring 200, which is continuous with the signal line 120 in the active area 3.

FIG. 12 is a G-G cross-sectional view of FIG. 10. FIG. 12 basically has the same configuration as FIG. 11 except that the electronic component 220 is mounted on the terminal wiring 200. However, in the G-G cross section depicted in FIG. 12, the width of the terminal wiring 200 is increased because the electronic component 220 is mounted.

In FIG. 11 and FIG. 12, the terminal wiring 200 is formed in the same layer as the signal lines 120 in the active area 5. On the other hand, the terminal wiring 200 may be formed in the same layer as the scanning lines 110 in the active area 5.

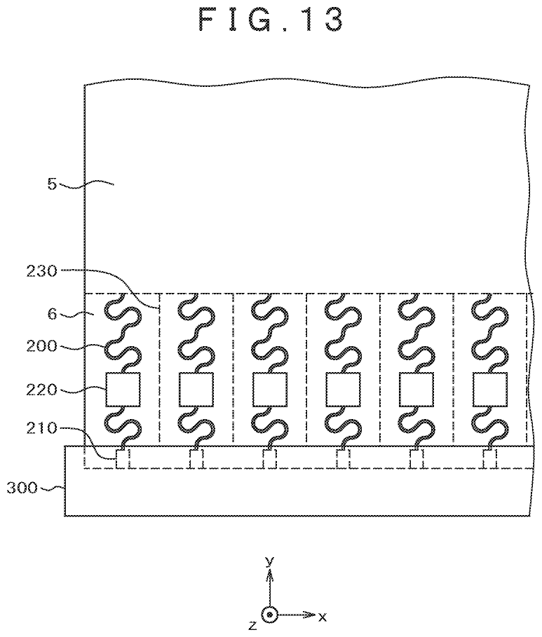

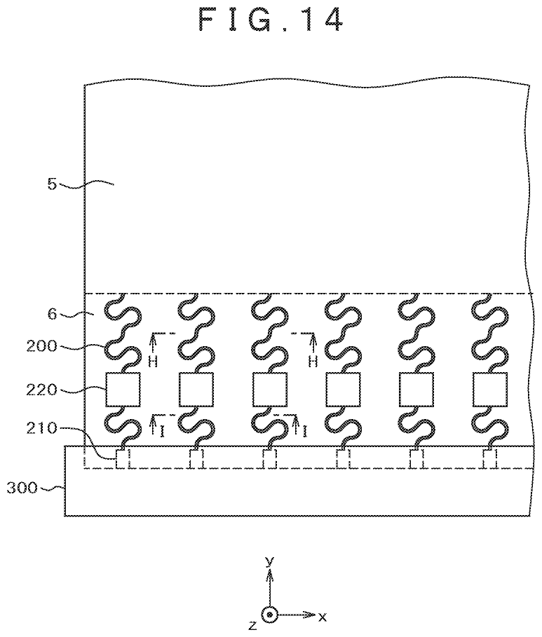

FIG. 13 is a plan view for depicting an example of a configuration that is made more extensible in the lateral direction (x direction) or the vertical direction (y direction) in the terminal area. In FIG. 14, the terminal wirings 200 having a meander structure extend in the vertical direction (y direction) and are aligned in the lateral direction. Between the lines of the terminal wirings 200, slits 230 like perforations are formed in the upper protective layer 3 and the lower protective layer 4 depicted in FIG. 9. The extensibility of the terminal area 6 can be made larger than that of the active area 5 by the slits 230.

### Second Embodiment

In the first embodiment, the electronic components 220 are mounted on the extensible terminal area 6 to form the configuration of the flexible wiring substrate 150 on the base material having the active area 5. As a result, the stress generated at the connection part with the flexible wiring substrate is reduced, and the reliability is improved. However, even in the configuration of the first embodiment, it is difficult to completely eliminate the stress in the terminal connecting the terminal area 6 to the wiring substrate 300.

In a second embodiment, the extensibility of a terminal area 6 is made smaller than that of an active area 5 in a stretchable electronic device, and thus excessive stress is prevented from being generated in the connection area with a wiring substrate 300. FIG. 14 is a plan view of a stretchable electronic device 1 in the second embodiment, and the appearance thereof is the same as FIG. 10 in first embodiment.

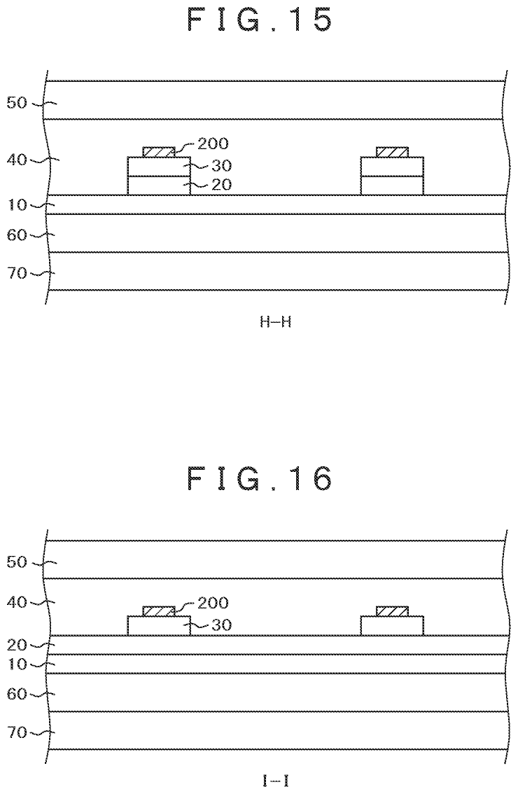

However, in the second embodiment, the cross-sectional structure of the terminal area 6 is different from that in FIG. 1. FIG. 15 is an H-H cross-sectional view of FIG. 14. In FIG. 15, a base material 10 is formed not in a meander structure but in a flat plate shape.

However, a first organic insulating film 20 and a second organic insulating film 30 maintain a meander structure. Therefore, the extensibility of the terminal area 6 is smaller than that of the active area. As a result, the stress between the wiring substrate 300 and the terminal area 6 caused by the difference in extensibility can be reduced.

FIG. 16 is an example of an I-I cross-sectional view of FIG. 14. In FIG. 16, the base material 10 and the first organic insulating film 20 are formed not in a meander structure but in a flat plate shape. However, the second organic insulating film 30 maintains a meander structure. Therefore, in the I-I cross section, the extensibility of the terminal area 6 is smaller than that of the active area 5 and that of the terminal area 6 in the H-H cross section. In other words, the extensibility of the terminal area 6 is smaller than that of other parts in the vicinity of the wiring substrate 300. Therefore, the stress between the wiring substrate 300 and the terminal area 6 in a terminal 210 can be reduced.

It should be noted that in FIG. 14, the cross-sectional configuration of the terminal area 6 is changed in two stages, but the two stages are not necessarily required, and effects can be obtained by only one stage.

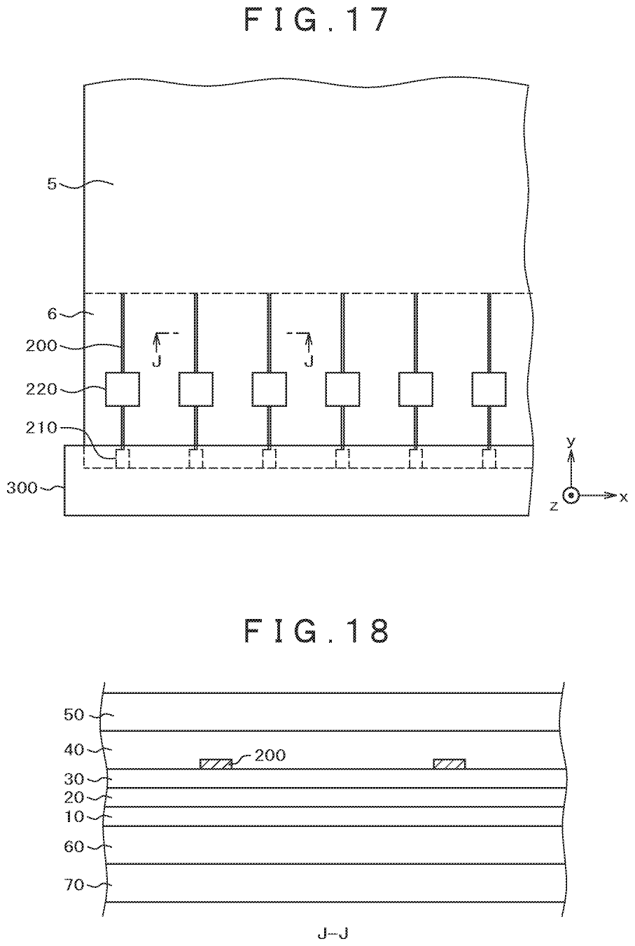

FIG. 17 depicts another configuration of the second embodiment and is a plan view of the terminal area 6 of the stretchable electronic device 1. In FIG. 17, in the terminal area 6, the terminal wirings 200 are straight lines rather than a meaner structure. That is, the terminal area 6 does not have an extensible structure.

FIG. 18 is a J-J cross-sectional view of FIG. 18. In FIG. 18, each of the base material 10, the first organic insulating film 20, and the second organic insulating film 30 has a planar structure and does not have an extensible structure.

In the configuration depicted in FIG. 17, since the terminal area 6 is not stretchable even in the stretchable electronic device 1, the stress caused by the difference in extensibility is not generated in the connection part between the wiring substrate 300 and the terminal area 6. On the other hand, the Young's modulus in the plane direction is different between the active area 5 and the terminal area 6, but since the signal lines 120 of the active area 5 and the terminal wirings 200 of the terminal area 6 are continuously formed, the noise caused by the connection is not generated.

What is claimed is:

1. An electronic device comprising:
a base material that has a meander structural part and an element area;
a wiring that is positioned at the meander structural part; and
an element that is positioned at the element area and is connected to the wiring, wherein
the electronic device has an active area and a terminal area,
in the active area, a plurality of the element areas are provided and the meander structural part is formed so as to connect the element areas to each other,
in the terminal area, a terminal connected to a wiring substrate is formed,
between the active area and the terminal of the terminal area, an electronic component is mounted,
the electronic component is connected to the wiring through a first terminal wiring positioned between the active area and the electronic component, and
the terminal is connected to the electronic component through a second terminal wiring positioned between the electronic component and the terminal.

2. The electronic device according to claim 1,
wherein the first terminal wiring has a same layer structure as a signal line of the active area.

3. The electronic device according to claim 1,
wherein the first terminal wiring has a same layer structure as a scanning line of the active area.

4. The electronic device according to claim 1,
wherein a plurality of the electronic components are formed, and a third terminal wiring connecting the plurality of electronic components to each other has a meander structure.

5. The electronic device according to claim 1,
wherein Young's modulus of the wiring substrate is larger than that of the base material.

6. An electronic device in which an active area and a terminal area are continuously formed, wherein
in the active area, a scanning line having a meander structure and a signal line having a meander structure are formed,
a terminal connected to a wiring substrate is formed in the terminal area,
a terminal wiring having a meander structure is formed in the terminal area, and
Young's modulus of the terminal area in a plane direction is larger than that of the active area in the plane direction.

7. The electronic device according to claim 6, wherein
a first organic insulating film positioned in the active area and the terminal area, and a second organic insulating film formed on the first organic insulating film are provided,
in the active area, the first organic insulating film and the second organic insulating film have a meaner structure, and
in the terminal area, the first organic insulating film is formed in a flat plate shape, and the second organic insulating film has a meander structure.

8. The electronic device according to claim 6,
wherein the electronic device includes a base material having a meander structural part where the scanning line and the signal line are formed, and an element area where an element connected to the scanning line and the signal line is formed.

9. The electronic device according to claim 8,
wherein the Young's modulus of the wiring substrate is larger than that of the base material.

10. An electronic device comprising:
a base material that has a meander structural part and an element area;
a wiring that is positioned at the meander structural part; and
an element that is positioned at the element area and is connected to the wiring, wherein
the electronic device has an active area and a terminal area,
in the active area, a plurality of the element areas are provided and the meander structural part is formed so as to connect the element areas to each other,
in the terminal area, the base material is formed in a flat plate shape and a terminal connected to a wiring substrate is formed,
in the terminal area, a linear terminal wiring is formed, and
Young's modulus of the terminal area in a plane direction is larger than that of the active area in the plane direction.

11. The electronic device according to claim 10,
wherein the Young's modulus of the wiring substrate is larger than that of the base material.
